(19) United States
(12) Patent Application Publication
(10) Pub. No.: US 2019/0019971 A1
(43) Pub. Date: Jan. 17, 2019

(54) Luminescent Device and Display Device Using Same

(71) Applicant: AAC Technologies Pte. Ltd., Singapore City (SG)

(72) Inventors: Zaifeng Xie, Shenzhen (CN); Da Huang, Shenzhen (CN); Chenhui Cao, Shenzhen (CN); Tengda Ma, Shenzhen (CN)

(21) Appl. No.: 15/955,871

(22) Filed: Apr. 18, 2018

(30) Foreign Application Priority Data
Jul. 14, 2017 (CN) 201710573116.8

(51) Int. Cl. H01L 51/50; H01L 51/56; H01L 51/00; C09K 11/06

(52) U.S. Cl. CPC H01L 51/5028; H01L 51/0058; H01L 51/5056; H01L 51/5004; H01L 51/56; H01L 51/001; C09K 11/06; H01L 2251/552; H01L 51/006; H01L 51/0061; H01L 51/0072; H01L 51/0052; H01L 51/0074; H01L 51/0071; C09K 2211/1018; H01L 51/5072

(57) ABSTRACT

The invention relates to the field of an organic luminescence technology, in particular to a luminescent device. The luminescent device of the invention includes a first electrode, a second electrode and at least a luminescent layer arranged between the first electrode and the second electrode. The luminescent layer contains at least a kind of host material for transmitting electrons, at least a kind of auxiliary material for transmitting holes, and at least a kind of thermal delayed fluorescence material for guest luminescence. The host and auxiliary materials form exciplex in the electroluminescence process. The invention increases the path of exciton energy transfer, makes full use of the energy in the exciton, and improves the luminescent efficiency of the luminescent device; while making electron injection and hole injection become easier, reducing the turn on voltage, and improving the efficiency roll-off phenomenon.

### FIELD OF THE PRESENT DISCLOSURE

The invention relates to the field of organic light emitting technology, in particular to a luminescent device and a display device using the luminescent device.

### DESCRIPTION OF RELATED ART

A luminescent device—Organic Light-Emitting Diode (OLED) comes into being and gradually enters the field of vision as a new generation of flat panel display technology. OLED is characterized by its own luminescence, unlike the thin-film transistor liquid crystal display (TFT-LCD), which requires backlight, so it has high visibility and brightness, followed by low voltage demand and high power saving efficiency. Coupled with fast reaction, light weight, thin thickness, simple construction and low cost etc, it is regarded as one of the most promising products in 21th century. At present, in the application of mobile phone screen, OLED replacing Liquid Crystal Display (LCD) has become the trend of the times. Some Samsung models of cell phones already use the OLED screen, and Apple Company has announced that all its phones will have OLED screens in 2018.

At the beginning of development, the structure of OLED was very simple, namely anode/luminescent layer (a luminescent material) EML/cathode. The device performance of such device structure is very poor, for example, the turn on voltage needs 14V. This is because, in general, the HOMO and LUMO of the luminescent material are very mismatched with the anode or cathode, resulting in difficulties in the hole or electron injection, and therefore, a very high turn on voltage is required. In addition, the luminescent layer EML has only one kind of luminescent material. In the electroluminescence process, the exciton concentration of the luminescence is very high, which leads to the quenching of the exciton, resulting in very low luminescence efficiency. For the application of OLED display or lighting, the device structure like this needs to be improved, especially for low turn on voltage, high luminescent efficiency, high quantum efficiency and long lifetime.

For this reason, a lot of improved device structures are proposed, and the two common techniques are multilayer structure and host-guest doping system. For example, the basic device structure of the present OLED is an anode/hole injection layer (HILL)/a hole transport layer (HTL)/a luminescent layer (EML)/an electron transport layer (ETL)/an electron injection layer (EIL)/a cathode. In such devices, each functional layer is responsible for a single function, leading to a great improvement in the performance of OLED. For example, HIL is a kind of hole injection, which reduces the barrier between the anode and HTL hole transport layer and reduces the turn on voltage; EIL is an electron injection layer that reduces the barrier between the cathode and the ETL electron transport layer and makes it more matched. EML adopts the host and guest doped system, andf the holes injected from the anode and the electrons injected from the cathode combine on the host material and form triplet and singlet excitons. In this way, the excitons are transferred to the triplet or the singlet of the guest material. When the energy is obtained from the triplet or the singlet of the guest material, the excitons need to be excited by photoluminescence due to its instability. This multilayer device structure significantly improves the performance of OLED. However, the traditional OLED structure needs to be further improved in terms of reducing the turn on voltage, improving the luminescent efficiency of OLED and prolonging the lifetime of OLED etc.

The luminescence mechanism of OLED mainly comprises fluorescence and phosphorescence, and the former mainly uses S₁ (singlet exciton)→S₀ from singlet excited state to single ground state process. The latter mainly uses the T1 (triplet exciton)→S₀ from triple excited state to the single ground state. For fluorescent OLED, when the current is driven, both holes and electron carriers are injected into the anode and cathode at the same time, and the carriers form 1 S₁ and 3 T₁ in the host material of the luminescent layer. Then the singlet exciton S₁ energy of the host material is transferred to the singlet S₁ of the host material, and finally luminescence occurs at the guest material S₁→S₀. The energy efficiency of this process is relatively low, because, ideally, 25% excitons(S₁) produced by electroluminescence are used in the photoluminescence of the guest material, while the exciton (T₁, host material) is wasted due to spin blocking. For phosphorescent OLED materials, when the current is driven, the holes and electron carriers injected at the anode and cathode at the same time form singlet and triplet excitons on the host material of EML. However, due to the heavy metal effect in phosphorescent OLED materials, the intersystem crossing from singlet to triplet can be enhanced, and 100% T₁ excitons can be obtained theoretically, thus obtaining higher luminescence efficiency. The performance of phosphorescent OLED in red light and green light has been improved compared with fluorescent OLED. However, the lifetime of phosphorescent OLED (PHOLED) and the performance attenuation at high current density are very serious, which seriously limits the further commercial application of PHOLED.

In order to improve the luminescence efficiency of OLED, thermal delayed fluorescence (TADF) has been proposed recently. Due to the very small energy difference of ΔE(S₁-T₁) from TADF materials, the original spin forbidden T₁→S₁ is possible by means of thermal process, and the efficiency of 100% can be achieved theoretically. However, this kind of TADF material is limited by the strict separation of the required material HOMO-LUMO, the triplet and singlet energy levels are very close to each other, so that the T₁ and S₁ energy levels of TADF materials are disturbed. Excitons can be transferred from T₁ to S₁ energy level, thus 100% fluorescence can be obtained theoretically.

In the traditional host-guest doped system of OLED devices, the efficiency roll-off is also very serious, whether the current fluorescent OLED or phosphorescent OLED. This is due to the fact that the HOMO or LUMO of the host material of the luminescent layer does not match the HOMO of the hole transport layer or the LUMO of the electron transport layer in this host and guest doped system. Especially the mismatch of LUMO leads to the imbalance between hole and electron carrier in OLED devices (in the original OLED, the mobility of hole carrier is much larger than that of electron carrier). When driven by a high current or at a high brightness, the superfluous hole carriers will be quenched between the SSA singlet (or the TTA triplet states) with the singlet of the luminescent material (or the triplet state of the phosphorescent material, or the quenching between TPA triplet and carrier), in order to make the brightness attenuation of OLED more obvious.

In view of this, the present invention is proposed.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a schematic diagram of a luminescent device in a specific embodiment of the present invention;

FIG. 2 is a schematic diagram of the luminescent mechanism of a luminescent device in a specific embodiment of the present invention;

FIG. 3 is a schematic diagram of the luminescent mechanism of another luminescent device in the specific embodiment of the present invention;

FIG. 4 is a schematic diagram of the luminescent mechanism of traditional luminescent devices;

FIG. 5 shows the UV absorption spectra of the thermal delayed fluorescence material G1 (HAP-3TPA);

FIG. 6 shows the photoluminescence spectra of the exciplex E1 (H1: A1);

FIG. 7 shows the UV absorption spectra of the thermal delayed fluorescence material G2 (FDQPXZ);

FIG. 8 shows the photoluminescence spectra of the exciplex E3 (H2: A2);

FIG. 9 shows the photoluminescence spectra of the host material H2, the auxiliary material A3 and the exciplex E4 (H2: A3);

FIG. 10 shows the photoluminescence spectra of the host material H2, the auxiliary material A4 and the exciplex E5 (H2: A4);

FIG. 11 is a schematic diagram of the structure of the display device in the embodiment of the present invention;

Of which,

1 is a UV absorption curve in FIG. 7;

2 is a fluorescence spectrum curve in FIG. 7;

3 is a phosphorescence curve in FIG. 7;

10—luminescent device;

11—first electrode;

12—hole transport layer;

13—luminescent layer;

14—electron transport layer;

15—second electrode.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

The present invention is further elaborated in combination with exemplary embodiments. It should be understood that these embodiments are used only to illustrate the invention and not to limit the scope in the invention.

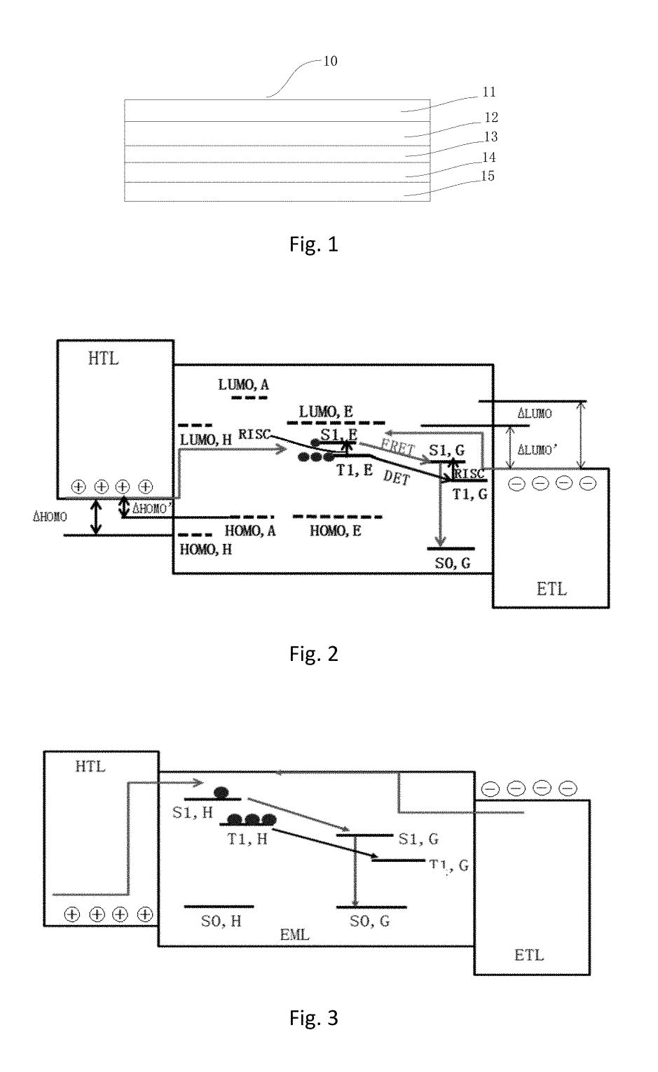

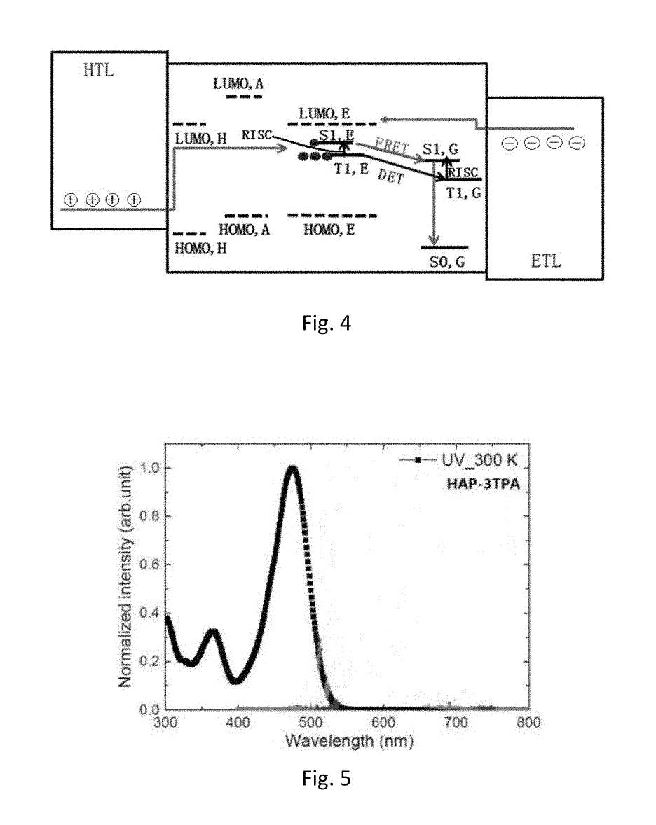

The invention provides a luminescent device 10, the structure of which is illustrated in FIG. 1, comprising a first electrode 11, a second electrode 15 and at least a luminescent layer 13 arranged between the first electrode 11 and the second electrode 15; the invention also comprises a hole transport layer 12 and an electron transport layer 14 relative to the hole transport layer 12, and the hole transport layer 12 and the electron transport layer 14 are arranged between the first electrode 11 and the second electrode 15; the luminescent organic layer 13 is arranged between the hole transport layer 12 and the electron transport layer 14.

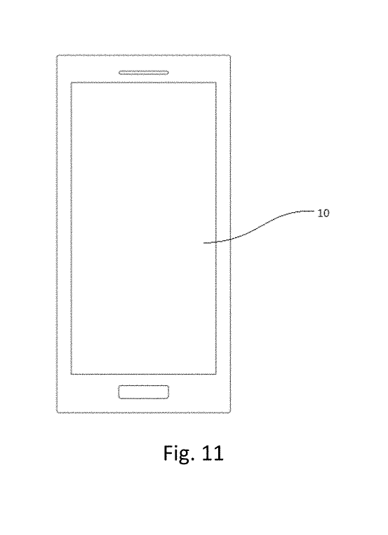

The embodiment of the invention also relates to a display device, including a luminescent device 10 of the present invention as shown in FIG. 11.

In the luminescent layer, there is at least a host material for transmitting electrons, at least an auxiliary material for transmitting holes, and at least a heat-delayed fluorescence material for guest luminescence.

The host and auxiliary materials form exciplex in the electroluminescence process when two molecules work together to emit a photon, a bimolecular complex is known as an exciplex.

The invention provides the host material, the auxiliary material and the thermal delayed fluorescence material simultaneously in the luminescent layer, and the exciplex formed in the luminescence process through the host material and the auxiliary material. Thus, the energy transfer path of exciton is increased, the energy in exciton is fully utilized, and the luminescent efficiency of luminescent device is improved. At the same time, the electron injection and hole injection will become easier, and it can reduce the turn on voltage, and improve the efficiency roll-off phenomenon in the host-guest doping system of traditional OLED devices.

Firstly, the luminescent device of the invention is further explained from the energy level's point of view.

In the luminescent device of the invention, the HOMO energy level of the host material is lower than the HOMO energy level of the auxiliary material, and the LUMO energy level of the host material is lower than the LUMO energy level of the auxiliary material. Thus, the exciplex can be formed in the electroluminescence process. The HOMO orbits of the exciplex are equal to the HOMO orbits of the auxiliary materials, and the LUMO orbits of the exciplex are equal to the LUMO orbits of the host materials. The schematic diagram is shown in FIG. 2; in FIG. 2, H denotes the host material, A denotes the auxiliary material, E denotes the exciplex, and G denotes the thermal delayed fluorescence material. As shown in FIG. 2, the HOMO-LUMO energy level of the resulting exciplex is lower than the HOMO-LUMO level of the host material.

In order to meet the need of energy transfer in the luminescent layer, the energy level of the HOMO-LUMO of the exciplex is higher than that of the thermal delayed fluorescence material, thus the host materials, exciplex and thermal delayed fluorescence materials form a decreasing energy level in the luminescent layer of the invention, which makes the electron injection and hole injection easier, thus reducing the turn on voltage, overcoming the technical defects of efficiency roll-off in the host-guest doping system of traditional OLED devices.

One of the characteristics of the exciplex is that the difference between the singlet energy level S1,E and its triplet energy level T1,E is very small. As shown in the energy conduction path in FIG. 2, the triplet exciton T1,E formed by the injected hole and electron on the exciplex can be partially transferred to S1,E via the RISC, and then transferred to S1G via FRET for photoluminescence; part of T1,E can also be transferred to T1,G via DET. Moreover, the energy level difference ΔEST between the singlet S1,G and the triplet T1,G is less than or equal to 0.3 eV, so it can be transferred back to S1,E via RISC for further photoluminescence. Through the RISC path of the exciplex and the RISC path of the thermal delayed fluorescence material, the triplet excitons (T1,E and T1,G) are fully utilized. Thus, the exciton utilization rate can reach 100%. In the luminescent device of the invention, the exciplex can use the FRET path and the EDT path to transfer the energy of all the singlet exciton S1,E and the triplet exciton T1,E to the singlet exciton S1,G or the triplet exciton T1,G of the thermal delayed fluorescence material, and the thermal delayed fluorescence material can use the singlet exciton for luminescence by using transferring the energy of all triplet exciton T1,G to the singlet exciton S1,G. Therefore, the luminescent device of the invention makes full use of the energy of the triplet exciton, makes the utilization ratio of the exciton reach 100%, and remarkably improves the quantum efficiency and the luminescent efficiency of the OLED.

Secondly, the luminescent device of the invention is further explained from the luminescent mechanism's point of view.

The luminescent mechanism of the luminescent device shown in FIG. 2 is taken as an example to further explain the luminescent device of the application from the luminescent mechanism's point of view. Among them, difference materials are chosen and used for the material of the hole transport layer and auxiliary material (the difference of HOMO energy level is not greater than 0.3 eV, so as to facilitate hole injection). The difference materials are chosen and used for the material of the electron transport layer and host material (the difference of HOMO energy level is not greater than 0.3 eV, so as to facilitate electron injection).

Specifically, the luminescent mechanism is divided into three steps:

Step 1: hole (denoted with +) and electron(denoted with −) are injected into OLED from anode and cathode, respectively, and the holes are transferred from the hole injection layer and hole transport layer to EML luminescent layer. Electrons are transferred from the electron injection layer and the electron transport layer to the EML luminescent layer.

Step 2: the formation of exciplex (E).

A low energy exciplex (E) is formed by the interaction between the host material (H) and the auxiliary material (A).

Step 3: exciton formation of exciplex (E) and energy transfer.

In step 3, during the formation of exciplex (E), the holes and electrons on the exciplex (E) form a 1: 3 singlet exciton SLE and a triplet exciton T1,E.

The energy transfer paths of S1,E and T1,E are as follows:

(1) Intramolecular Energy Transfer:

Because that ΔE(S1,E-T1,E) in exciplex is close to 0 eV, the exciplex may have reverse intersystem crossing (RISC): T1,E→S1,E.

(2) Intermolecular Energy Transfer:

(2.1) Because that the spin of the excited state is the same, the exciplex (E) can transfer the energy of the singlet exciton to the singlet exciton of the thermal delayed fluorescence guest luminescent material (G) via Forster Energy Transfer (FET): S1,E→S1,G.

(2.2) At the same time, there are a few excitons in the triplet state of exciplex (E), and the exciplex (E) is closely related to the thermal delayed fluorescence material (G), and the excitons in the triplet state of exciplex (E) can transfer energy to the excitons in the triplet state of the thermal delayed fluorescence material (G) by Dexter Energy Transfer (DET): T1,E→T1,G.

The energy transfer between above two molecules and their process of competing with each other cannot be ignored. FET is the most important mode of energy transfer in host-guest doped system. The energy transfer process between host and guest excitons of S1→S1, S1→T1 is a process of remote energy transfer. For example, in fluorescent OLED, the singlet excitons of the host material can only be transferred to the triplet of the luminescent material, which is the main mode of energy transfer.

DET is another short-range energy transfer mode competing with FET, which occurs when the distance between host and guest molecules is closer, and the distance between molecules is several Angstroms. The exciton energy transfer of triplet occurs between the host and guest of T1→T1.

The schematic diagram of the traditional OLED device is shown in FIG. 3, which only involves the type of FET energy transfer, neglecting the DET energy transfer, so the exciton energy loss of DET device is large, with low efficiency.

In step 3, the excitons of exciplex (E) are transferred to the singlet excitons and triplet excitons of the thermal delay fluorescence material, and the energy transfer path is as follows:

(1) The delayed fluorescence emission process from singlet excitons to ground state of the thermal delayed fluorescence material (G) with the same spin is: S1,G→S0,G.

(2) For the delayed fluorescence emission process from triplet excitons to ground state of the thermal delayed fluorescence material (G) with the different spins, because the thermal delayed fluorescence material ΔE(S1,G-T1,G) is less than or equal to 0.3 eV, the triplet excitons of the thermal delayed fluorescence material (G) can be transferred back to its singlet excited stateby RISC: T1,G→S1,G. Then, the delayed fluorescence emission process from the singlet exciton to ground state: S1,G→S0,G.

As mentioned earlier, the material and the auxiliary material of the hole transport layer may be chosen from the materials having different HOMO energy levels, or the materials having the same or similar HOMO energy levels , and the proximity of HOMO energy levels refers to that the difference is less than or equal to 0.3 eV.

As mentioned earlier, the material and the host material of the electron transport layer may be chosen from the materials having different LUMO energy levels, or the materials having the same or similar LUMO energy levels, and the proximity of LUMO energy levels refers to that the difference is less than or equal to 0.3 eV.

The magnitude of the turn on voltage of the device is related to the interface energy barrier to be overcome in the process of the hole or electron being injected into the luminescent layer. The larger the energy barrier, the greater the turn on voltage. The material using HOMO energy level less than or equal to 0.3 eV can be used for hole injection or electron injection.

If the same material is used, the energy level difference between the hole transport layer material and the auxiliary material is close to 0, and the hole injection has no energy barrier limit, which reduces the turn on voltage of the device to the maximum extent.

Furthermore, as an improvement of the luminescent device of the invention, the hole transport layer material is made of the material with energy level that is close to or the same as the HOMO energy level of the auxiliary material. The electron transport layer material is made of material with energy level that is the same or close to the LUMO energy level of the host material. As mentioned earlier, the HOMO orbit of the exciplex is equivalent to the HOMO orbit of the auxiliary material, and the LUMO orbit of the exciplex is equivalent to the LUMO orbit of the host material. Therefore, by selecting and optimizing the materials of the hole transport layer and the electron transport layer, the injection of electrons and holes can be made easier, thus significantly reducing the barrier between the anode and the hole transport layer, in order to effectively reduce the turn on voltage; At the same time, the barrier between the cathode and the ETL electron transport layer is effectively reduced to make it more matched, which effectively improves the rate efficiency roll-off phenomenon and the luminescent efficiency is further improved.

Thirdly, the luminescent device of the invention is further explained from the material′ point of view.

The host material and auxiliary material of the luminescent device of the invention can be chosen from the fluorescent organic material or the phosphorescent organic material, further preferably, at least one of the host material and the auxiliary material is chosen from the fluorescent organic material.

As one of the structural bases of the host material and the auxiliary material in the luminescent device of the invention, the molecular structure formula of the host material contains an electron-absorbing group, and the molecular structure formula of the auxiliary material contains an electron-donating group. In the process of electroluminescence, the electron-absorbing group of the host materials is easy to obtain the anionic species formed by the electrons, and the electron-donating group in the auxiliary materials is apt to lose the cationic species formed by the electrons. Cation species and anionic species form exciplex by complexation.

In the invention, the structure formed by the host material obtaining electrons is known as the anionic species, and the structure formed by the auxiliary material losing the electrons is known as the cationic species.

As an improvement of the luminescent device of the invention, the host material is chosen from at least one of the electronic transport materials, and the auxiliary material is chosen from at least one of the hole transport materials, thereby further improving the luminescent efficiency.

As an improvement of the luminescent device of the invention, the mass ratio of the host material to the auxiliary material is 99:1˜51:49.

Finally, the luminescent device of the invention is further explained from the point of view of spectral characteristics.

Through experimental verification, the emission main peak of the exciplex in the luminescent device of the invention is partially or completely separated from the emission main peak of the host material and the auxiliary material, thereby further verifying the formation of the exciplex.

The emission main peak of the exciplex emission spectrum of the invention overlaps with the maximum absorption peak of the thermal delayed fluorescence material absorption spectrum in the visible wavelength range. Among them, the emission spectrum is photoluminescence spectrum and the absorption spectrum is ultraviolet absorption spectrum.

Further preferably, the wavelength of the main emission peak of the fluorescence emission spectrum of the exciplex is greater than or equal to the wavelength of the maximum absorption peak in the visible wavelength range of the absorption spectrum of the thermal delayed fluorescence material. Thus, the exciplex can transfer energy to the triplet or singlet states of the thermal delay fluorescence material, and avoid the energy inversion to make the exciplex E luminescent.

Device Fabrication

The ITO substrate is a 30 mm×30 mm bottom emitting glass with four luminescent regions, covering a luminescent area of 2 mm×2 mm, and a transmittance of ITO thin film is 90%@550 nm, and its surface roughness Ra<1 nm, and its thickness is 1300A, with square resistance of 10 ohms per square meters.

The cleaning method of ITO substrate as follows: first it is placed in a container filled with acetone solution, and the container is placed in ultrasonic cleaning machine for 30 minutes, in order to dissolve and remove most of the organic matter attached to the surface of ITO; and then the cleaned ITO substrate is removed and placed on the hot plate for half an hour at high temperature of 120° C., in order to remove most of the organic solvent and water vapor from the surface of the ITO substrate; and then the baked ITO substrate is transferred to the UV-ZONE equipment for processing with O3 Plasma, and the organic matter or foreign body which could not be removed on the ITO surface is further processed by plasma, and the processing time is 15 minutes, and the finished ITO is quickly transferred to the film forming chamber of the OLED evaporation equipment.

OLED preparation before evaporation: first of all, the OLED evaporation equipment is prepared, and then IPA is used to wipe the inner wall of the chamber, in order to ensure that the whole film chamber is free of foreign bodies or dust. Then, the crucible containing OLED organic material and the crucible containing aluminum particles are placed on the position of organic evaporation source and inorganic evaporation source in turn. By closing the cavity and taking the initial vacuum and high vacuum, the internal evaporation degree of OLED evaporation equipment can reach 10 E -7 Torr.

OLED evaporation film: the OLED organic evaporation source is opened to preheat the OLED organic material at 100° C. for 15 minutes to ensure the further removal of water vapor from the OLED organic material. Then the organic material that needs to be evaporated is heated rapidly and the baffle over the evaporation source is opened until the evaporation source of the material runs out and the wafer detector detects the evaporation rate, and then the temperature rises slowly, the temperature rise is 1˜5° C., until the evaporation rate is stable at 1 A/s, the baffle directly below the mask plate is opened and the OLED film is formed. When it is observed that the organic film on the ITO substrate reaches the preset film thickness at the computer end, the mask baffle and the evaporative source directly above the baffle are closed, and the evaporative source heater of the organic material is closed. The evaporation process for other organic and cathode metal materials is described above. When evaporating the host material and auxiliary material in the luminescent layer, the solid film of exciplex is formed by controlling the evaporation rate of the host material and auxiliary material.

OLED encapsulation process: the cleaning and processing of 20mm×20mm encapsulation cover is as the same as the pretreatment of ITO substrate. The UV adhesive coating or dispensing is carried out around the epitaxial of the cleaned encapsulation cover, and then the encapsulation cover of the finished UV adhesive is transferred to the vacuum bonding device, and stuck with the ITO substrate of the OLED film in vacuum, and then transferred to the UV curing cavity for UV-light curing at wavelength of 365 nm. The light-cured ITO devices also need to undergo post-heat treatment at 80° C. for half an hour, so that the UV adhesive material can be cured completely.

### Embodiment 1

The luminescent device of the invention is constructed as follows: ITO/HIL/HTL/H:A:G /ETL/EIL/cathode. Among them, the chemical structures of the host material H1, the auxiliary material Al and the thermal delayed fluorescence material G1 (HAP-3TPA) are as follows.

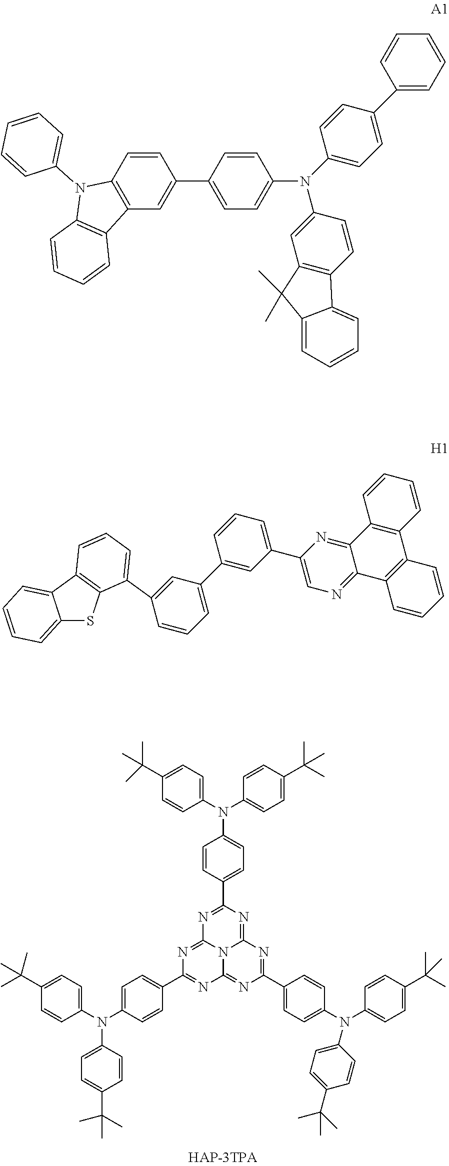 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1cc(-c2cccc(-c3cccc4c3sc3ccccc34)c2)cc(-c2cnc3c4ccccc4c4ccccc4c3n2)c1 ; CC(C)(C)c1ccc(N(c2ccc(C3=NC4=NC(c5ccc(N(c6ccc(C(C)(C)C)cc6)c6ccc(C(C)(C)C)cc6)cc5)=NC5=NC(c6ccc(N(c7ccc(C(C)(C)C)cc7)c7ccc(C(C)(C)C)cc7)cc6)=NC(=N3)N45)cc2)c2ccc(C(C)(C)C)cc2)cc1]

Analysis of Material Properties:

In the above materials, the dibenzothiophene and diazo ring of the host material H1 form an electron absorption group, which is an organic material with a partial electron transport. The auxiliary material A1 contains carbazole and trianiline functional groups to form an electron-donating group, which is an organic material for transporting holes. Thus, the exciplex can be formed in the electroluminescence process of the host material and the auxiliary material.

Analysis of Energy Levels and Spectral Characteristics:

The HOMO and LUMO energy levels of the thermal delayed fluorescence material G1 (HAP-3TPA) are 5.6 eV and 3.4 eV, respectively, and the singlet and triplet energy levels are 2.38 eV and 2.21 eV, ΔE_{ST}=0.17 eV, respectively. When HAP-3TPA is used as a guest material, its UV absorption spectrum is shown in FIG. 5. When HAP-3TPA is used as the guest material, there is a strong absorption peak at 400 nm-510 nm. The maximum absorption peak in the visible wavelength range is about 470 nm.

The triplet energy level of the host material H1 is T_{1,H}=2.41 eV, and the triplet energy level of the auxiliary material A1 is T_{1,A}=2.44 eV. If the host material H1 and the auxiliary material A1 form the triplet energy level T_{1,E}=2.3 eV of the exciplex E (H1: A1) according to 8: 2, the singlet energy level of the exciplex E is as follows: S_{1,E}=2.32 eV, ΔE_{ST}=0.02 eV.

Among them, the triplet energy level is calculated by T₁=1240/λ peak (low temperature phosphorescence spectrum), and the singlet energy level is calculated by S₁=1240/λ peak (fluorescence spectrum).

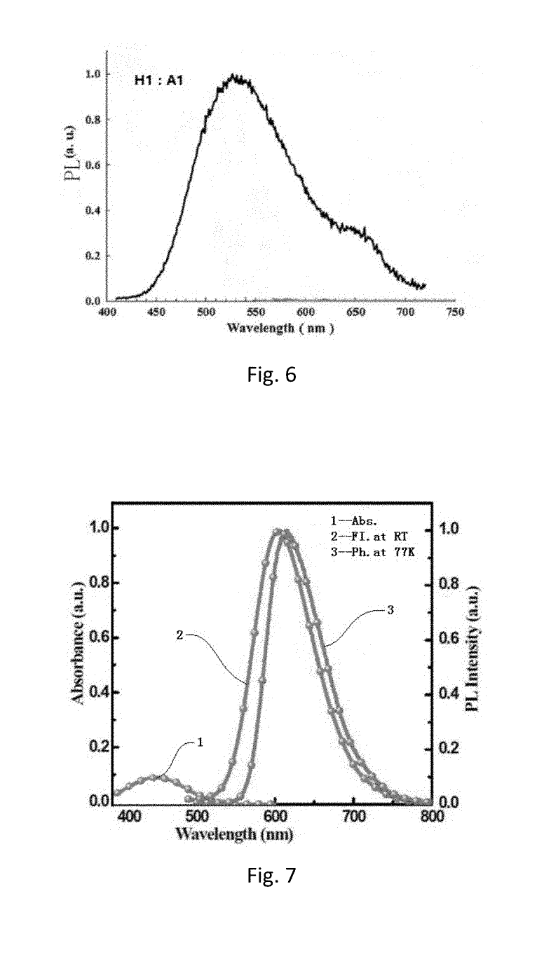

According to the above method, a solid state membrane forming exciplex E1 (H1: A1) is prepared. The photoluminescence spectra (PL spectra) of the exciplex formed by doping the host material H1 and the auxiliary material A1 by 8: 2 is determined, as shown in FIG. 6. The main emission peak of photoluminescence spectrum is between 450 nm and 700 nm, and the main peak is 540 nm.

Comparing the PL spectra of exciplex E1 (H1: A1) shown in FIG. 6 with the UV absorption spectra of HAP-3TPA shown in FIG. 5, we can see that there is a good spectral overlap between them. The wavelength of the main emission peak of the exciplex E1 (H1: A1) is larger than that of the maximum absorption peak in the visible wavelength range of the HAP-3TPA absorption spectrum of the thermal delayed fluorescence material. Therefore, in the structure of the device 1, the exciplex E can transfer energy to the triplet or singlet states of the thermal delayed fluorescence material HAP-3TPA, avoiding the energy reversal to cause the exciplex E to emit light.

Testing of Device Performance:

1. No.1 OLED device is fabricated by using the above method and material, and the structure of the device 1 is as follows:

ITO/HIL/HTL/H1: A1: HAP-3TPA (H1: A1=8:2,94 wt %) /ETL/EIL/cathode.

Among them, the weight percentage of host material and auxiliary material in EML layer is H1: A1=8: 2, and the weight percentage of thermal delayed fluorescence material HAP-3TPA accounting for EML luminescent layer is 6 wt %.

The turn on voltage, the maximum external quantum efficiency and efficiency roll-off performance of the encapsulated OLED devices are tested, and the experimental results are shown in Table 1.

The test methods are as follows: the experimental data of the turn on voltage, the external quantum efficiency and efficiency roll-off are measured using McScience M6100 and M6000 equipment (performance change when the efficiency at 0.1 mA/cm2 reaches 100 mA/cm²).

2. No. R1 comparison device by using the above method and the material is a traditional device structure, which contains a single host and guest doping system, and its specific structure is as follows: (1)

ITO/HIL/HTL/H1: HAP-3TPA/ETL/EIL/cathode.

The turn on voltage, the maximum external quantum efficiency and efficiency roll-off performance of the encapsulated OLED devices are tested, and the experimental results are also shown in Table 1.

TABLE 1

| | | Maximum external | |
|---|---|---|---|
| Device | Turn on | quantum efficiency | Efficiency |
| number | voltage (V) | EQE(%) | roll-off (%) |
| 1 | 2.6 | 22.7% | 8% |
| R1 | 3.5 | 17.5% | 30% |

Table 1 show that the performance of the device 1 of the invention is significantly higher than that of the comparison device R1.

### Embodiment 2

The luminescent device of the invention is constructed as follows: ITO/HIL/HTL/H:A:G/ETL/EIL/cathode. Among them, the chemical structure of the thermal delayed fluorescence material G2 (FDQPXZ) is as follows, and the host material H1 and the auxiliary material Al are the same as embodiment 1.

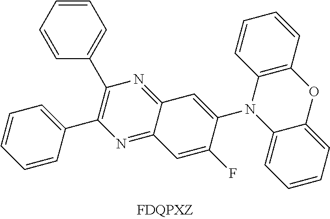 [SMILES: Fc1cc2nc(-c3ccccc3)c(-c3ccccc3)nc2cc1N1c2ccccc2Oc2ccccc21]

Analysis of energy level and spectral characteristics:

The HOMO and LUMO energy levels of the thermal delayed fluorescence material G2(FDQPXZ) are 5.06 eV and 2.91 eV, respectively. The singlet and triplet energy levels are 2.05 eV and 2.01 eV, ΔE_{ST}=0.04 eV, respectively.

When FDQPXZ is used as a guest material, its UV absorption and fluorescence emission spectra are shown in FIG. 7. From FIG. 7, we can see that FDQPXZ has a strong absorption peak at 400 nm-500 nm. The maximum absorption peak in the visible wavelength range is about 450 nm (curve 1). In addition, compared with the main emission peaks of the phosphorescence spectrum (curve 3) and the fluorescence emission spectrum (curve 2) of FDQPXZ shown in FIG. 7, the wavelength difference between the two main emission peaks is very small. It is further verified that the difference between the singlet and triplet energy levels ΔE_{ST} of the thermal delayed fluorescence material FDQPXZ is less than 0.3 eV.

The triplet energy level of the host material H1 is 2.41 ev, and the triplet energy level of the auxiliary material A1 is 2.44 ev. If the host material H1 and the auxiliary material A1 form the triplet energy level T_{1,E}=2.3 eV of the exciplex E1 (H1: A1) according to 8: 2, the singlet energy level of the exciplex E1 is as follows: S_{1,E}=2.32 eV.

Comparing FIG. 7 with the PL spectra of exciplex E1 (H1: A1) formed by the host material H1 and A1 shown in FIG. 6, we can see that there is a good spectral overlap between them, and the wavelength of the main emission peak of the exciplex E1 (H1: A1) is larger than that of the maximum absorption peak in the visible wavelength range of the FDQPXZ UV absorption spectrum of the thermal delayed fluorescence material. Therefore, in the structure of the device 2, the exciplex E can transfer the energy to the triplet or singlet states of the thermal delayed fluorescence material FDQPXZ, avoiding the energy reversal to cause the exciplex E to emit light.

Testing of Device Performance:

1. No.2 OLED device is fabricated by using the above method and material, and the structure of the device 2 is as follows:

ITO/HIL/HTL/H1: A1: FDQPXZ (H1: A1=8:2,95wt %) /ETL/EIL/cathode.

Among them, the weight percentage of the host material and auxiliary material in EML layer is H1: A1=8: 2, and the weight percentage of thermal delayed fluorescence material HAP-3TPA accounting for EML luminescent layer is 5 wt %.

The turn on voltage, the maximum external quantum efficiency and efficiency roll-off performance of the encapsulated OLED devices are tested, and the testing method is as the same as the embodiment 1 the experimental results are shown in Table 1.

2. No. R2 comparison device by using the above method and the material is a traditional device structure, which contains a single host and guest doping system, and its specific structure is as follows:

ITO/HIL/HTL/H1: FDQPXZ/ETL/EIL/cathode.

The turn on voltage, the maximum external quantum efficiency and efficiency roll-off performance of the encapsulated OLED devices are tested, and the experimental results are also shown in Table 2.

TABLE 2

| | | Maximum external | |
|---|---|---|---|
| Device | Turn on | quantum efficiency | Efficiency |
| number | voltage(V) | EQE (%) | roll-off (%) |
| 2 | 2.3 | 18.2% | 5% |
| R2 | 2.8 | 13.5% | 14% |

As can be seen from Table 2, the performance of the device 2 of the invention is significantly higher than that of the comparison device R2.

### Embodiment 3

The luminescent device of the invention is constructed as follows: ITO/HIL/HTL/H: A: G/ETL/EIL/cathode. Among them, the chemical structures of the host material H2 and the auxiliary material A2 are as follows, and the thermal delay fluorescence material G1 (HAP 3TPA) is the same as the embodiment 1.

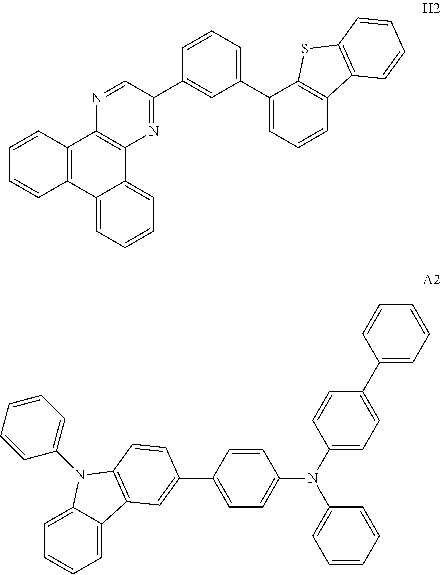 [SMILES: c1cc(-c2cnc3c4ccccc4c4ccccc4c3n2)cc(-c2cccc3c2sc2ccccc23)c1 ; c1ccc(-c2ccc(N(c3ccccc3)c3ccc(-c4ccc5c(c4)c4ccccc4n5-c4ccccc4)cc3)cc2)cc1]

Analysis of Material Properties:

In the material mentioned above, the host material of H2 contains an electron-absorbing group formed by dibenzothiophene and diazo heterocycle, which is a host material for transporting electrons, and A2 is an auxiliary material for transporting holes, which contains the electron-donating groups formed by trianiline and carbazole functional groups, in order to form the exciplex in the electroluminescence process.

Analysis of Energy Level and Spectral Characteristics:

The HOMO and LUMO energy levels of the thermal delayed fluorescence material HAP-3TPA are 5.6 eV and 3.4 eV, respectively, and the singlet and triplet energy levels are 2.38 eV and 2.21 eV, respectively, ΔE_{ST}=0.17 eV. The UV absorption spectrum is shown in FIG. 5. There is a strong absorption peak at 400 nm-510 nm, and the maximum absorption peak in the visible wavelength range is about 470 nm.

The HOMO and LUMO energy levels of H2 are 6.21 eV and 2.95 eV, respectively, Δ_{HOMO-LUMO}=3.26 eV, and the triplet energy levels are 2.40 eV, and the singlet energy level is 2.91 EV; the HOMO and LUMO energy levels of the auxiliary material A2 are 5.43 eV and 1.99 eV respectively, Δ_{HOMO-LUMO}=3.44 eV, and the triplet energy level is 2.46 ev, and the singlet energy level is 3.07v; if the host material H2 and the auxiliary material A2 form the triplet energy level T_{1,E}=2.37 eV of the exciplex E3 (H2: A2) according to 8: 2, the singlet energy level of the exciplex E is as follows: S_{1,E}=2.32 eV, Δ_{HOMO-LUMO}=2.48 eV. Among them, the triplet energy level is calculated by T₁=1240/λ peak (low temperature phosphorescence spectrum), and the singlet energy level is calculated by S₁=1240/λ peak (fluorescence spectrum).

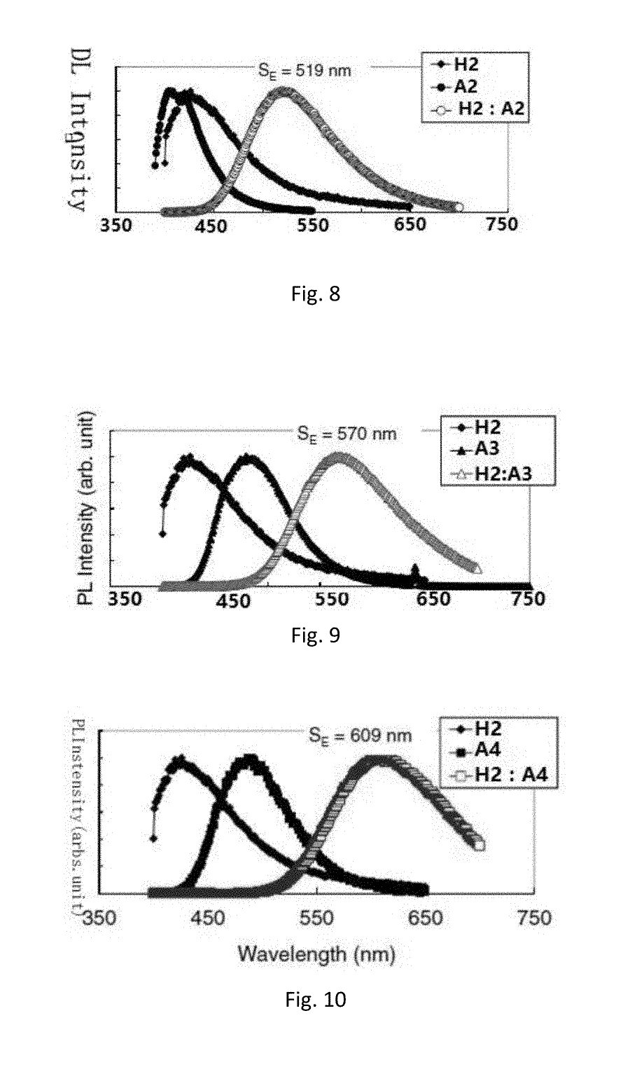

At the same time, the photoluminescence spectra of the host material H2 and the auxiliary material A2 are determined; A solid-state membrane is prepared to form an exciplex E3 (H2: A2) and its photoluminescence spectra is determined as shown in FIG. 8. It can be seen from FIG. 8 that the exciplex E3 (H2: A2) is distributed between 450 nm and 650 nm in PL spectra, and its main peak is at 519 nm. The main peak of the host material H2 is about 410 nm, and the main peak of the auxiliary material A2 is about 400 nm. Therefore, it is confirmed that the emission spectra of the host material H2 and the auxiliary material A2 are different from those of the host material H2 and the auxiliary material A2, which means the formation of a new exciplex E(H2: A2).

Moreover, the PL spectra of the exciplex E3 (H2: A2) shown in FIG. 8 are compared with the UV absorption spectra of the thermal delayed fluorescence material HAP-3TPA shown in FIG. 5. There is good spectral overlap between the two in the wavelength range of 450 nm to 510 nm.

It can be seen that the exciplex E3 (H2: A2) can effectively reduce Δ_{HOMO-LUMO}, which is convenient for injection of the holes or electrons and driving voltage of HOMO-LUMO compared with the host material H2 or auxiliary material A2; at the same time, the splitting energy of the singlet and triplet states of ΔE_{(S1-T1)} is also reduced, which is good for the transfer of all the excitons to the singlet states and the triplet states of the thermal delayed fluorescence materials, in order to improve quantum efficiency and luminescence efficiency. In the structure of the device 3, the exciplex E3 can transfer energy to the triplet state or the singlet state of the thermal delayed fluorescence material HAP-3TPA, avoiding the energy reversal to cause the exciplex E3 to emit light.

Testing of Device Performance:

1. No.3 OLED device is fabricated by using the above method and material, and the structure of the device 3 is as follows:

ITO/HIL/HTL/H2: A2: HAP-3TPA (H2: A2=8:2,96wt %) /ETL/EIL/cathode.

Among them, the weight percentage of the host material and auxiliary material in EML layer is H2: A2=8: 2; and the weight percentage of thermal delayed fluorescence material HAP-3TPA accounting for EML luminescent layer is 4 wt %.

The turn on voltage, the maximum external quantum efficiency and efficiency roll-off performance of the encapsulated OLED devices are tested, and the specific experimental results are shown in Table 3.

2. No. R3 comparison device by using the above method and the material is a traditional device structure, which contains a single host and guest doping system, and its specific structure is as follows:

ITO/HIL/HTL/H2: HAP-3TPA/ETL/EIL/cathode.

The turn on voltage, the maximum external quantum efficiency and efficiency roll-off performance of the encapsulated OLED devices are tested, and the specific experimental results are also shown in Table 3.

TABLE 3

| | | Maximum external | Efficiency |
|---|---|---|---|
| Device | Turn on | quantum efficiency | roll-off |
| number | voltage (V) | EQE (%) | (%) |
| 3 | 2.7 | 21.3% | 11.3% |
| R3 | 3.4 | 15.5% | 27.8% |

Table 3 shows that the performance of the device 3 of the invention is significantly higher than that of the comparison device R3.

### Embodiment 4

The luminescent device of the invention is constructed as follows: ITO/HIL/HTL/H: A: G/ETL/EIL/cathode. Among them, the chemical structure of the auxiliary material A3 is as follows, and the host material H2 is the same as embodiment 3 and the thermal delayed fluorescence material G2 (FDQPXZ) is the same as the embodiment 2.

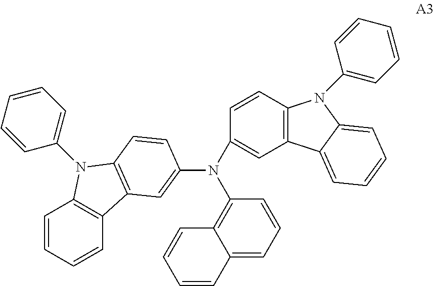 [SMILES: c1ccc(-n2c3ccccc3c3cc(N(c4ccc5c(c4)c4ccccc4n5-c4ccccc4)c4cccc5ccccc45)ccc32)cc1]

Analysis of Material Properties:

The host material H2 is a kind of electron transport material, which has an electron absorption group. Auxiliary material A3 is a hole-type transport material in which the carbazole and trianiline can form electron donor groups which can form exciplex in the electroluminescence process.

Analysis of energy level and spectral characteristics:

The HOMO and LUMO energy levels of the thermal delayed fluorescence material G2 (FDQPXZ) are 5.06 eV and 2.91 eV, respectively, and the singlet and triplet energy levels are 2.05 eV and 2.01 eV, respectively, ΔE_{ST}=0.04 eV. The UV absorption spectrum is shown in FIG. 7. According to FIG. 7, there is a strong absorption peak at 400 nm-510 nm for the guest material G2 (FDQPXZ), and the maximum absorption peak in the visible wavelength range is about 470 nm.

The HOMO and LUMO energy levels of H2 are 6.21 eV and 2.95 eV, respectively, Δ_{HOMO-LUMO}=3.26 eV, and the triplet energy level is 2.40 eV, and the singlet energy level is 2.91 EV; the HOMO and LUMO energy levels of the auxiliary material A3 are 5.19 eV and 2.13 eV respectively, Δ_{HOMO-LUMO}=3.06 eV, and the triplet energy level is 2.21 ev, and the singlet energy level is 2.59 v; if the host material H2 and the auxiliary material A3 form the triplet energy level T_{1,E}=2.18 eV of the exciplex E4 (H2: A3) according to 8: 2, the singlet energy level of the exciplex E is as follows: S_{1,E}=2.20 eV, Δ_{HOMO-LUMO}=2.24 eV. Among them, the triplet energy level is calculated by T₁=1240/λ peak (low temperature phosphorescence spectrum), and the singlet energy level is calculated by S₁=1240/λ peak (fluorescence spectrum).

It can be seen that the exciplex E3 (H2: A3) can effectively reduce Δ_{HOMO-LUMO}, which is convenient for injection of the holes or electrons and driving voltage of HOMO-LUMO compared with the host material H2 or auxiliary material A2; at the same time, the splitting energy of the singlet and triplet states of ΔE_{(S1-T1)} is also reduced, which is good for the transfer of all the excitons to the singlet states and the triplet states of the thermal delayed fluorescence materials, in order to improve quantum efficiency and luminescence efficiency. In the structure of the device 4, the exciplex E4 can transfer energy to the triplet state or the singlet state of the thermal delayed fluorescence material FDQPXZ, avoiding the energy reversal to cause the exciplex E4 to emit light.

A solid-state membrane forming an exciplex E4 (H2: A3) is prepared by above method, and its photoluminescence spectra of the exciplex E4 (H2: A3) formed by doping the host material H2 and auxiliary material A3 is shown in FIG. 9. It can be seen from FIG. 9 that the exciplex E4 (H2: A3) is distributed between 450 nm and 700 nm in PL spectra, and its main peak is at 570 nm. The main peak of the host material H2 is about 410 nm, and the main peak of the auxiliary material A3 is about 470 nm. Therefore, it is confirmed that the emission spectra of the host material H2 and the auxiliary material A3 are different from those of the host material H2 and the auxiliary material A3, which means the formation of a new exciplex E4 (H2: A3).

Moreover, the PL spectra of the exciplex E4 (H2: A3) shown in FIG. 9 are compared with the UV absorption spectra of the thermal delayed fluorescence material G2 (FDQPXZ) shown in FIG. 7. There is good spectral overlap between the two in the wavelength range of 450 nm to 500 nm.

Testing of Device Performance:

1. No.4 OLED device is fabricated by using the above method and material, and the structure of the device 4 is as follows:

ITO/HIL/HTL/H2: A3: FDQPXZ (H2: A3=8:2,94wt %) /ETL/EIL/cathode.

Among them, the weight percentage of the host material and auxiliary material in EML layer is H2: A3=8: 2; and the weight percentage of thermal delayed fluorescence material FDQPXZ accounting for EML luminescent layer is 6 wt %.

The turn on voltage, the maximum external quantum efficiency and efficiency roll-off performance of the encapsulated OLED devices are tested, and the specific experimental results are shown in Table 4.

2. No. R4 comparison device by using the above method and the material is a traditional device structure, which contains a single host and guest doping system, and its specific structure is as follows:

ITO/HIL/HTL/H2: HAP-3TPA/ETL/EIL/cathode.

The turn on voltage, the maximum external quantum efficiency and efficiency roll-off performance of the encapsulated OLED devices are tested, and the specific experimental results are also shown in Table 4.

TABLE 4

| | | Maximum external | |
|---|---|---|---|
| Device | Turn on | quantum efficiency | Efficiency |
| number | voltage (V) | EQE(%) | roll-off (%) |
| 4 | 2.4 | 18.3% | 6% |
| R4 | 2.8 | 13.5% | 14% |

Table 4 shows that the performance of the device 4 of the invention is significantly higher than that of the comparison device R4.

This is because, it can be seen that the exciplex E4 (H2: A3) can effectively reduce Δ_{HOMO-LUMO}, which is convenient for injection of the holes or electrons and driving voltage of HOMO-LUMO compared with the host material H2 or auxiliary material A3; at the same time, the splitting energy of the singlet and triplet states of ΔE_{(S1-T1)} is also reduced, which is good for the transfer of all the excitons to the singlet states and the triplet states of the thermal delayed fluorescence materials, in order to improve quantum efficiency and luminescence efficiency.

At the same time, in the structure of the device 4, the exciplex E4 can transfer energy to the triplet state or the singlet state of the thermal delayed fluorescence material FDQPXZ, avoiding the energy reversal to cause the exciplex E4 to emit light.

### Embodiment 5

The luminescent device of the invention is constructed as follows: ITO/HIL/HTL/H: A: G/ETL/EIL/cathode. The chemical structure of the auxiliary material A4 is as follows: the host material H2 is the same as embodiment 3, and the thermal delayed fluorescence material G2 (FDQPXZ) is the same as the embodiment 2.

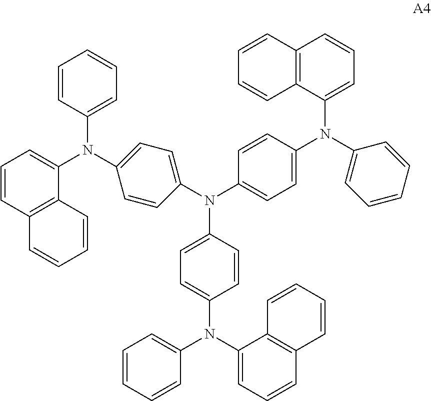 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1]

Analysis of Material Properties:

Among above materials, the host material H2 is a kind of electron transport material, which has an electron absorption group. The auxiliary material A3 is a hole-type transport material in which the carbazole and trianiline can form electron donor groups which can form exciplex in the electroluminescence process.

Analysis of energy level and spectral characteristics:

1. The HOMO and LUMO energy levels of the thermal delayed fluorescence material FDQPXZ are 5.06 eV and 2.91 eV, respectively, and the singlet and triplet energy levels are 2.05 eV and 2.01 eV, respectively, ΔE_{ST}=0.04 eV.

2. The HOMO and LUMO energy levels of the host material H2 are 6.21 eV and 2.95 eV, respectively, Δ_{HOMO-LUMO}=3.26 eV, and the triplet energy level is 2.40 eV, and the singlet energy level is 2.91 EV; the HOMO and LUMO energy levels of the auxiliary material A4 are 4.98 eV and 2.17 eV respectively, Δ_{HOMO-LUMO}=2.81 eV, and the triplet energy level is 2.25 eV, and the singlet energy level is 2.53 eV.

if the host material H2 and the auxiliary material A4 form the triplet energy level T_{1,E}=2.02 eV of the exciplex E5 (H2: A4) according to 8: 2, the singlet energy level of the exciplex E5 is as follows: S_{1,E}=2.04 eV, Δ_{HOMO-LUMO}=2.03 eV. Among them, the triplet energy level is calculated by T₁=1240/λ peak (low temperature phosphorescence spectrum), and the singlet energy level is calculated by S₁=1240/λ peak (fluorescence spectrum).

It can be seen that in the structure of the device 5, the triplet and singlet states of the excimer E5 are slightly lower than the triplet or singlet states of the thermal delayed fluorescence material FDQPXZ. Therefore, the exciton energy in the luminescent layer may reverse the excimer complex E5 and cause the excimer complex E4 to emit light.

A solid-state membrane forming an exciplex E5 (H2: A4) is prepared by above method, and its photoluminescence spectra of the exciplex E5 (H2: A4) formed by doping the host material H2 and auxiliary material A4 is shown in FIG. 11. It can be seen from FIG. 11 that the exciplex E5 (H2: A4) is distributed between 510 nm and 750 nm in PL spectra, and its main peak is at 609 nm. The main peak of the host material H2 is about 410 nm, and the main peak of the auxiliary material A4 is about 500 nm. Therefore, by FIG. 11, it is confirmed that the emission spectra formed by doping layer of the host material H2 and the auxiliary material A4 are different from those of the host material H2 and the auxiliary material A4, which means the formation of a new exciplex E5 (H2: A4).

The UV absorption spectra of the thermal delayed fluorescence material G2 (FDQPXZ) are shown in FIG. 7. Compared FIG. 11 with 7, the PL spectra of exciplex E5 (H2: A4) and the UV absorption spectra of thermal delayed fluorescence material G2 (FDQPXZ) are not well overlapped in spectra.

Testing of Device Performance

1. No.5 OLED device is fabricated by using the above method and material, and the structure of the device 5 is as follows:

ITO/HIL/HTL/H2: A4: FDQPXZ (H2: A4=8:2,94wt %) /ETL/EIL/cathode.

The turn on voltage, the maximum external quantum efficiency and efficiency roll-off performance of the encapsulated OLED devices are tested, and the specific experimental results are shown in Table 5.

Among them, the weight percentage of the host material and auxiliary material in EML layer is H2: A3=8:2; and the weight percentage of thermal delayed fluorescence material FDQPXZ accounting for EML luminescent layer is 6 wt %.

2. No. R5 comparison device by using the above method and the material is a traditional device structure, which contains a single host and guest doping system, and its specific structure is as follows:

ITO/HIL/HTL/H2: HAP-3TPA/ETL/EIL/cathode.

The turn on voltage, the maximum external quantum efficiency and efficiency roll-off performance of the encapsulated OLED devices are tested, and the specific experimental results are also shown in Table 5.

TABLE 5

| | | Maximum external | |
|---|---|---|---|
| Device | Turn on | quantum efficiency | Efficiency |
| number | voltage (V) | EQE (%) | roll-off (%) |
| 5 | 2.4 | 6.1% | 29% |
| R5 | 2.8 | 13.5% | 14% |

According to Table 5, the performance of device R5 is superior to that of device 5.

Although the exciplex E5 (H2: A3) can effectively reduce Δ_{HOMO-LUMO}, which is convenient for injection of the holes or electrons and reducing driving voltage, compared with the host material H2 or auxiliary material A3; at the same time, the splitting energy of the singlet and triplet states of ΔE_{(S1-T1)} is also reduced significantly, which makes the energy of the singlet states and the triplet states of the exciplex E5 is slightly lower than that of thermal delayed fluorescence materials FDQPXZ. Therefore, the exciton energy formed under the electric action cannot be transferred to the exciplex E5 for luminescence, which reduces the performance of the device.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A luminescent device comprising: a first electrode, a second electrode and at least a luminescent layer arranged between the first electrode and the second electrode; wherein
the luminescent layer comprises at least a host material for transmitting electrons, at least an auxiliary material for transmitting holes, and at least a thermal delayed fluorescence material for guest luminescence;
the host and auxiliary materials form exciplex by electroluminescence process.

2. The luminescent device as described in claim 1, wherein HOMO energy level of the host material is lower than that of the auxiliary material, and LUMO energy level of the host material is lower than that of the auxiliary material.

3. The luminescent device as described in claim 2, wherein HOMO-LUMO level of the exciplex is lower than that of the host material.

4. The luminescent device as described in claim 2, wherein HOMO-LUMO level of the exciplex is higher than that of the thermal delayed fluorescence material.

5. The luminescent device as described in claim 1,wherein the exciplex is a bimolecular complex which transfers the energy of the triplet exciton to the singlet exciton of the exciplex.

6. The luminescent device as described in claim 5, wherein the exciplex is a bimolecular complex which transfers the energy of all singlet and triplet excitons to the singlet excitons or triplet excitons of the thermal delayed fluorescence material.

7. The luminescent device as described in claim 1, wherein the thermal delay fluorescence material is a material which transfers the energy of all the triplet excitons to the singlet state excitons of the thermal delayed fluorescence material and makes use of the singlet state excitons for luminescence.

8. The luminescent device as described in claim 1, wherein the energy level difference ΔE_{ST} of the thermal delayed fluorescence material is less than or equal to 0.3 ev in the singlet state and the triplet state.

9. The luminescent device as described in claim 1, wherein the main emission peak of the fluorescence emission spectrum of the exciplex overlaps with the maximum absorption peak of the thermal delayed fluorescence material in the visible wavelength range.

10. The luminescent device as described in claim 9, wherein the emission peak of the emission spectrum of the exciplex is greater than or equal to the wavelength of the maximum absorption peak of the absorption spectrum of the thermal delayed fluorescence material in the visible wavelength range.

11. The luminescent device as described in claim 1, wherein at least one of the host material and the auxiliary material is selected from the fluorescent organic material.

12. The luminescent device as described in claim 1, wherein the molecular structure of the host material contains an electron-absorbing group, and the molecular structure of the auxiliary material contains an electron-donating group.

13. The luminescent device as described in claim 12, wherein the host material obtains an anionic species formed by electrons, and the auxiliary material loses cationic species formed by electrons; the anionic species and the anionic species meridian form the exciplex.

14. The luminescent device as described in claim 1, wherein the host material is selected from at least one of the electronic transport type materials and the auxiliary material is selected from at least one of the hole transmission type materials.

15. The luminescent device as described in claim 1, wherein the mass ratio of the host material to the auxiliary material is 99:1˜51:49.

16. The luminescent device as described in claim 1 further including a hole transport layer and an electronic transport layer relative to the hole transport layer, wherein the hole transport layer and the electron transport layer are arranged between the first electrode and the second electrode; and the luminescent organic layer is arranged between the hole transport layer and the electron transport layer; a difference between the material of the hole transport layer and the HOMO level of the auxiliary material is less than or equal to 0.3 eV.

17. The luminescent device described in claim 1 further including a hole transport layer and an electronic transport layer relative to the hole transport layer, wherein the hole transport layer and the electron transport layer are arranged between the first electrode and the second electrode; the luminescent organic layer is arranged between the hole transport layer and the electron transport layer; a difference between the material of the electron transport layer and the LUMO energy level of the host material is less than or equal to 0.3 eV.

18. A display device comprising a luminescent device as described in claim 1.
